(19) United States
(12) Patent Application Publication
(10) Pub. No.: US 2008/0075998 A1
(43) Pub. Date: Mar. 27, 2008

(54) Electrolyte membrane for electrochemical cell and a method of producing the same

(76) Inventors: Tatsumi Ishihara, Fukuoka (JP); Takashi Yamada, Ibaraki (JP)

Correspondence Address: WENDEROTH, LIND & PONACK, L.L.P., 2033 K STREET N. W., SUITE 800, WASHINGTON, DC, 20006-1021, US

(21) Appl. No.: 11/525,127

(22) Filed: Sep. 22, 2006

(51) Int. Cl. H01M 8/10; C23C 14/00

(52) U.S. Cl. 429/33; 204/192.1

(57) ABSTRACT

[Problem to be Solved]

To provide an electrolyte membrane for electrochemical cells excellent in oxide ion permeability, and a method of producing the same.

[Solution]

An electrolyte membrane for electrochemical cells that is made of an oxide ion conductor having a component composition expressed by a general formula: La_{1-X}Sr_{X}Ga_{1-Y}Mg_{Y}O₃ (where X=0.05 to 0.3, and Y=0.025 to 0.3), and having a perovskite type crystal structure, wherein the electrolyte membrane has a thickness of 1 to 10 μm and a columnar crystal structure grown to a membrane surface in a direction perpendicular to a membrane face, and wherein the perovskite type crystal structure of the electrolyte membrane having the columnar crystal structure grown to the membrane surface, has a crystal structure with [112] direction oriented perpendicularly to the membrane face.

[Selected Drawing] None

### TECHNICAL FIELD

The present invention relates to an electrolyte membrane for an electrochemical cell which is used as an electrolyte membrane of a power generation cell for a solid electrolyte fuel cell, an electrolyte membrane of an oxygen pump cell and the like.

### BACKGROUND ART

Generally, it is known to use a lanthanum gallate based oxide ion conductor as one of electrolyte membranes for electrochemical cells, and this lanthanum gallate based oxide ion conductor has a component composition expressed by a general formula: La_{1-X}Sr_{X}Ga_{1-Y}Mg_{Y}O₃ (where X=0.05 to 0.3, Y=0.025 to 0.3). The oxide ion conductor is manufactured by sintering a formed body produced by press forming a compound oxide powder obtained by grinding a pre-sintered body, which is obtained by making La₂O₃ powder, SrCO₃ powder, Ga₂O₃ powder, and MgO powder mixed and blended, and then pre-sintered. It is known that the oxide ion conductor made of the sintered body obtained in this way has a perovskite crystal structure.

It is known that an electrolyte membrane made of the oxide ion conductor having the perovskite crystal structure is used as a solid electrolyte membrane in a power generation cell of a low-temperature type solid electrolyte fuel cell (see patent document 1), and further used as an electrolyte membrane of an oxygen pump cell in an oxygen concentrator (see patent document 2). Also, it is known that the electrolyte membrane having more excellent oxide ion permeability is more excellent as a solid electrolyte membrane in a power generation cell, and further exhibits excellent performance as an electrolyte membrane in an oxygen pump cell.

[Patent document 1] Japanese Patent Laid-Open No. 11-335164

[Patent document 2] Japanese Patent Laid-Open No. 2004-132876

### DISCLOSURE OF THE INVENTION

### Problems to be Solved by the Invention

However, the oxide ion permeability of the presently known electrolyte membrane is not sufficient. Therefore, the power generation efficiency of a solid electrolyte fuel cell incorporating a power generation cell using the conventional electrolyte membrane as a solid electrolyte membrane, is not yet sufficient. Further, the condensation efficiency of an oxygen concentrator incorporating an oxygen pump cell using the conventional electrolyte membrane, is not sufficient.

### MEANS FOR SOLVING THE PROBLEMS

Accordingly, the present inventors have carried out a study in order to develop an electrolyte membrane for electrochemical cells which is more excellent in oxide ion permeability. As the results of the study, the present inventors have obtained the following findings.

(a) When an electrolyte membrane made of an oxide ion conductor which has a component composition expressed by a general formula: La_{1-X}Sr_{X}Ga_{1-Y}Mg_{Y}O₃ (where X=0.05 to 0.3, and Y=0.025 to 0.3), and has a perovskite type crystal structure, is produced by a physical vapor deposition method, the electrolyte membrane tends to have a columnar crystal structure grown in a direction perpendicular to a membrane face. In the electrolyte membrane having the columnar crystal structure grown in the direction perpendicular to the membrane face, [112] direction of the perovskite type crystal structure is oriented perpendicularly to the membrane face, thereby enabling the electrolyte membrane to have further excellent oxide ion permeability.

(b) It is preferred that the electrolyte membrane produced by the physical vapor deposition method is a thin membrane having a thickness within a range of 1 to 10 μm.

The present invention has been made on the basis of the above described results of the study and is characterized by:

(1) an electrolyte membrane for electrochemical cells that is excellent in oxide ion permeability, and is made of an oxide ion conductor having a component composition expressed by a general formula: La_{1-X}Sr_{X}Ga_{1-Y}Mg_{Y}O₃ (where X=0.05 to 0.3, and Y=0.025 to 0.3), and having a perovskite type crystal structure, wherein the electrolyte membrane has a columnar crystal structure grown to a membrane surface in a direction perpendicular to a membrane face, and wherein the perovskite-type crystal structure of the electrolyte membrane having the columnar crystal structure grown to the membrane surface, has a crystal structure with [112] direction oriented perpendicularly to the membrane face;

(2) the electrolyte membrane for electrochemical cells excellent in oxide ion permeability, as described in (1), having a membrane thickness of 1 to 10 μm; and

(3) an electrochemical cell wherein a cathode membrane is formed on one of the faces of the electrolyte membrane for electrochemical cells excellent in oxide ion permeability, as described in one of (1) and (2), and an anode membrane is formed on the other face.

The electrolyte membrane for electrochemical cells excellent in oxide ion permeability, as described in one of (1) and (2), is incorporated as a solid electrolyte membrane of a power generation cell for a solid electrolyte fuel cell, to produce the power generation cell for the solid electrolyte fuel cell. It is possible to further improve the performance of the solid electrolyte fuel cell produced by using the power generation cell for the solid electrolyte fuel cell. Therefore, the present invention is characterized by:

(4) a power generation cell for a solid electrolyte fuel cell, wherein an air electrode membrane is formed on one of the faces of the electrolyte membrane for electrochemical cells excellent in oxide ion permeability, as described in one of (1) and (2), and a fuel electrode membrane is formed on the other face of the electrolyte; and

(5) a solid electrolyte fuel cell incorporating the power generation cell for the solid electrolyte fuel cell as described in (4).

Further, an oxygen pump cell is produced by using the electrolyte membrane for electrochemical cells excellent in oxide ion permeability, as described in one of (1) and (2). It is possible to further improve the performance of an oxygen concentrator produced by incorporating the oxygen pump cell. Therefore, the present invention is characterized by:

(6) an oxygen pump cell wherein air electrode membranes are formed on both faces of the electrolyte membrane for electrochemical cells excellent in oxide ion permeability, as described in one of (1) and (2); and

(7) an oxygen concentrator incorporating the oxygen pump cell as described in (6).

In the case where the above described electrolyte membrane for electrochemical cells excellent in oxide ion permeability is produced by a physical vapor deposition method, the electrolyte membrane produced by the physical vapor deposition method has a fine and excellent perovskite type crystal structure. However, a membrane thickness less than 1 μm is not sufficient as a thickness of the electrolyte membrane for electrochemical cells. On the other hand, when the membrane thickness of the electrolyte membrane for electrochemical cells exceeds 10 μm, a portion which is not formed into the columnar crystal structure grown in the direction perpendicular to the membrane face, tends to be produced. Thus, a portion in which [112] direction of the perovskite crystal structure of the electrolyte membrane for electrochemical cells is not oriented perpendicularly to the membrane face, tends to be produced, which is not preferred. Therefore, the thickness of the electrolyte membrane for electrochemical cells excellent in oxide ion permeability, according to the present invention, is set to 1 to 10 μm.

The electrolyte membrane for electrochemical cells excellent in oxide ion permeability, according to the present invention, is obtained by performing membrane formation using a target under a certain oxygen partial pressure by a physical vapor deposition method (preferably by a pulsed laser ablation method), and the physical vapor deposition is preferably performed in an oxygen atmosphere at an oxygen partial pressure of 0.001 to 0.1 atm. This is because if the oxygen partial pressure is higher than 0.1 atm, the membrane quality of the electrolyte membrane for electrochemical cells is not formed to be fine and, on the other hand, if the oxygen partial pressure is set to be lower than 0.001 atm, a sufficient membrane forming rate cannot be obtained.

In order to form the electrolyte membrane for electrochemical cells excellent in oxide ion permeability, according to the present invention, by the pulsed laser ablation method, a laser beam is converged on the target to increase the temperature of the target at once, so that the target components are volatilized to be deposited in the form of a thin membrane on a substrate facing the target. As the substrate used at this time, a fuel electrode plate and an air electrode plate can be used when a power generation cell for a solid electrolyte fuel cell is produced. Further, when an oxygen pump cell is produced, an air electrode plate can be used as the substrate. At this time, the findings that Mg in particular escapes to the outside of the reaction system, causing the ratio at which Mg is deposited on the substrate, to be extremely low, and that the deposition ratios of other metallic elements become high relatively to the deposition ratio of Mg, and that the deposition ratios are delicately different according to the metallic elements, were obtained.

On the basis of such findings, membrane forming experiments were repeated. As a result, it was found that an electrolyte membrane for electrochemical cells excellent in oxide permeability can be obtained by performing the physical vapor deposition in an oxygen atmosphere using a target made of a sintered body obtained in a manner that La₂O₃ powder, SrCO₃ powder, Ga₂O₃ powder, and MgO powder are blended and mixed so as to contain 71 to 81% (preferably 75 to 77%) of La, 66 to 106% (preferably 81 to 91%) of Sr, 66 to 76% (preferably 70 to 73%) of Ga, and 250 to 290% (preferably 265 to 275%) of Mg, with respect to a target composition of the electrolyte membrane for electrochemical cells expressed by the general formula La_{1-X}Sr_{X}Ga_{1-Y}Mg_{Y}O₃ (where X=0.05 to 0.3, Y=0.025 to 0.3), and are then sintered. It was also found that when the component composition is not settled within the above described ranges, a membrane having the target composition cannot be obtained.

Therefore, the present invention is characterized by:

(8) a producing method of the electrolyte membrane for electrochemical cells excellent in oxide ion permeability, as described in one of (1) and (2), wherein a physical vapor deposition is performed in an oxygen atmosphere using a target made of a sintered body obtained in a manner that La₂O₃ powder, SrCO₃ powder, Ga₂O₃ powder, and MgO powder are blended and mixed so as to contain 71 to 81% of La, 66 to 106% of Sr, 66 to 76% of Ga, and 250 to 290% of Mg, with respect toatarget composition of the electrolyte membrane for electrochemical cells, and are then sintered;

(9) the producing method of the electrolyte membrane for electrochemical cells excellent in oxide ion permeability, as described in (8), wherein the physical vapor deposition is performed in an oxygen atmosphere under an oxygen partial pressure of 0.001 to 0.1 atm; and

(10) the producing method of the electrolyte membrane for electrochemical cells excellent in oxide ion permeability, as described in one of (8) and (9), wherein the physical vapor deposition is performed by a pulsed laser ablation method.

### ADVANTAGES OF THE INVENTION

An electrolyte membrane for electrochemical cells according to the present invention, is more excellent in oxide ion permeability as compared with a conventional electrolyte membrane for electrochemical cells. Thus, a solid oxide fuel cell incorporating a power generation cell produced by using the electrolyte membrane for electrochemical cells according to the present invention, is capable of performing power generation much more efficiently than a conventional solid oxide fuel cell. An oxygen concentrator incorporating an oxygen pump cell in which air electrode membranes are formed on both faces of the electrolyte membrane for electrochemical cells according to the present invention, is also capable of performing oxygen concentration much more efficiently than a conventional oxygen concentrator.

### BEST MODE FOR CARRYING OUT THE INVENTION

### EXAMPLE 1

First, La₂O₃ powder, SrCO₃ powder, Ga₂O₃ powder, and MgO powder were prepared, and these powders were weighed so as to be set as La: 14.19 atomic %, Sr: 2.10 atomic %, Ga: 9.63 atomic %, Mg: 22.88 atomic %, and O: 51.20 atomic %. The weighed powders were blended and mixed by a ball mill, and then heated and retained in air at 1200° C. for three hours. The obtained clumped sintered body was coarsely ground by a hammer mill and then finely ground by a ball mill, so that a lanthane gallate based electrolyte raw powder having an average grain diameter of 1.3 μm was manufactured. The lanthane gallate based electrolyte raw powder was press formed to produce a disc-like formed body. The obtained formed body was heated and retained in air at 1450° C. for six hours, so that a disc-like target made of a disc-like lanthane gallate based electrolyte having a thickness of 5 mm and a diameter of 120 mm was produced.

Further, 1 mol of sodium hydroxide aqueous solution was dropped into a mixed aqueous solution containing 8 parts by weight of 0.5 mol/L cerium nitrate aqueous solution and 2 parts by weight of 0.5 mol/L samarium nitrate aqueous solution while stirring, so as to co-precipitate cerium oxide and samarium oxide. The co-precipitated cerium oxide and samarium oxide were filtered and then washed by repeating stirring, cleaning and filtering in pure water six times, to produce a co-precipitation powder of cerium oxide and samarium oxide. The co-precipitation powder was heated and retained in air at a temperature of 1000° C. for three hours, to produce a samarium doped ceria (hereinafter referred to as SDC) powder having a composition of (Ce_{0.8}Sm_{0.2})O₂ and an average grain diameter of 0.8 μm. A mixed powder was produced by blending and mixing the SDC powder and a NiO powder at a ratio between the SDC powder and the NiO powder=4:6. The mixed powder was press formed to produce a formed body, so that an anode plate was produced and prepared by retaining the formed body at a temperature of 1300° C. for three hours.

Further, Sm₂O₃ powder, SrCO₃ powder, and CoO powder were prepared and weighed so as to yield a composition expressed by (Sm_{0.5}Sr_{0.5})CoO₃. The powders were mixed by a ball mill and then heated and retained in air at 1000° C. for three hours. The obtained powder was finely ground by a ball mill, to produce a samarium strontium cobaltite based cathode raw powder having an average grain diameter of 1.1 μm. The samarium strontium cobaltite based cathode raw powder was mixed with an organic binder solution in which polyvinyl butylal and N-dioctyl phthalate were dissolved in a toluene-ethanol mixed solvent, to produce and prepare the slurry.

The target previously produced was set in a pulsed laser ablation apparatus, and the anode plate previously prepared as a substrate was also set in the pulsed laser ablation apparatus. The pulsed laser ablation method under the following conditions was carried out in an atmosphere under the oxygen partial pressure shown in Table 1 while retaining the conditions during the time period shown in Table 1, as a result of which electrolyte membranes for electrochemical cells having the thickness shown in Table 1 and a component composition of (La_{0.9}Sr_{0.1}) (Ga_{0.8}Mg_{0.2})O₃ were formed on the anode plate. The cross section of the electrolyte membranes for electrochemical cells obtained in this way was observed by a scanning electron microscope (SEM), and the observation result is shown in Table 1. Further, the orientation of perovskite crystal structure was investigated by X-ray diffraction, and the investigation result is shown in Table 1.

### <Pulsed Laser Ablation conditions>

Laser energy: 300 mJ,

Laser spot size: 10 mm²,

Laser energy density: 3 J/cm²

Laser repetition frequency: 30 Hz,

Atmosphere gas: Oxygen,

Further, the previously prepared slurry containing the samarium strontium cobaltite based cathode raw powder, was applied on the electrolyte membrane for electrochemical cells previously formed on the anode plate by the screen printing method, at a thickness of 30 μm, and dried, and thereafter, was heated and retained in air at 1100° C. for five hours so that a cathode membrane was baked on the electrolyte membrane, to thereby produce electrochemical cells 1 to 7 according to the present invention and comparison electrochemical cells 1 to 4, each of which cells has a cathode membrane formed in one of the faces of the electrolyte membrane for electrochemical cells, and the anode membrane formed on the other face.

Platinum wires were respectively connected to the anode plate and the cathode membrane of the electrochemical cells 1 to 7 according to the present invention and the comparison electrochemical cells 1 to 4, which were obtained as described above, and the platinum wires were connected to an ammeter. Hydrogen was made to flow into the anode plate side of the electrochemical cell so that the anode plate side was held in a hydrogen atmosphere, while air was made to flow into the cathode membrane side so that the cathode membrane side was held in an air atmosphere. In such state, a fixed voltage of 0.7 V was applied between the anode plate and the cathode membrane, and a current flowing at this time was measured. The oxide ion permeability of the electrolyte membranes for electrochemical cells was evaluated by the measurement results shown in Table 1.

### CONVENTIONAL EXAMPLE 1

Powders of lanthanum oxide, strontium carbonate, gallium oxide, magnesium oxide, and cobalt oxide, which were prepared in the Example 1, were prepared, and weighed to yield a composition expressed by (La_{0.9}Sr_{0.1}) (Ga_{0.8}Mg_{0.2})O₃. The powders were mixed by a ball mill and then heated and retained in air at 1200° C. for three hours. The obtained clumped sintered body was coarsely ground by a hammer mill and then finely ground by a ball mill, so that a lanthane gallate based electrolyte raw powder was produced. The lanthane gallate based electrolyte raw powder was mixed with an organic binder solution in which polyvinyl butylal and N-dioctyl phthalate were dissolved in a toluene-ethanol mixed solvent, to form the slurry. The slurry was formed in the form of a thin plate by a doctor blade method and cut out into a circle, and then heated and retained in air at 1450° C. for six hours so as to be sintered. In this way, a conventional electrolyte membrane for electrochemical cells made of a disc-like lanthane gallate based electrolyte membrane having a thickness of 200 μm and a diameter of 120 mm was produced. The cross section of the electrolyte membrane for conventional electrochemical cells made of the lanthane gallate based electrolyte plate obtained in this way was observed by the scanning electron microscope (SEM), and the observation result is shown in Table 1. Further, the orientation of perovskite crystal structure of the electrolyte membrane was investigated by X-ray diffraction, and the investigation result is shown in Table 1.

The SDC powder produced in the Example 1 and the NiO powder were mixed to produce the slurry for one of the faces of the electrolyte membrane for electrochemical cells made of the lanthane gallate based electrolyte plate. The slurry was applied on the one of the faces of the lanthane gallate based electrolyte plate at a thickness of 30 μm by the screen printing method, and dried, and thereafter, was heated and retained in air at 1200° C. for five hours, so that an anode membrane made of the SDC mixed with the NiO powder was formed and baked. The slurry containing the samarium strontium cobaltite based cathode raw powder was applied on the other face of the electrolyte membrane for electrochemical cells made of the lanthane gallate based electrolyte plate at a thickness of 30 μm by the screen printing method, and dried, and thereafter, was heated and retained in air at 1100° C. for five hours, so that a cathode membrane was baked. In this way, a conventional electrochemical cell was produced.

Platinum wires were respectively connected to the anode membrane and the cathode membrane of the conventional electrochemical cell with the anode plate formed on one of the faces thereof and the cathode membrane formed on the other face, and were connected to an ammeter. The anode membrane side of the electrochemical cell was held in the hydrogen atmosphere, while the cathode membrane side was held in the air atmosphere. In such state, the fixed voltage of 0.7 V was applied between the anode membrane and the cathode membrane, and a current flowing at this time was measured. The oxide ion permeability of the conventional electrolyte membrane for electrochemical cells was evaluated by the measurement result shown in Table 1.

[Table 1]

From a comparison of the electrochemical cells 1 to 7 according to the present invention and the conventional electrochemical cell, based on the results shown in Table 1, it can be seen that current values of the electrochemical cells 1 to 7 according to the present invention are higher than that of the conventional electrochemical cell, and hence, the electrolyte membrane used for the electrochemical cells 1 to 7 according to the present invention, is more excellent in oxide ion permeability than the electrolyte membrane used for the conventional electrochemical cell. Further, it can also be seen that the current values of the electrolyte membrane used for comparison electrochemical cells 1 to 4 are slightly lower than those of the electrolyte membrane used for the electrochemical cells 1 to 7, according to the present invention, and hence, are slightly inferior in oxide ion permeability to the electrolyte membrane used for the electrochemical cells 1 to 7 according to the present invention.

### EXAMPLE 2

Porous fuel electrode current collectors were respectively laminated on the anode plates of the electrochemical cells 1 to 7 according to the present invention, and of the comparison electrochemical cells 1 to 4, which cells were produced in the Example 1, while porous air electrode current collectors were respectively laminated on the cathode membranes of the electrochemical cells 1 to 7 according to the present invention, and of the comparison electrochemical cells 1 to 4. Further, separators were laminated on the porous fuel electrode current collectors and the porous air electrode current collectors, respectively. In this way, solid electrolyte fuel cells 1 to 7 and comparison solid electrolyte fuel cells 1 to 4 were produced.

### CONVENTIONAL EXAMPLE 2

A porous fuel electrode current collector was laminated on the anode plate of the conventional electrochemical cell produced in the conventional example 1, while a porous air electrode current collector was laminated on the cathode membrane of the conventional electrochemical cell. Further, separators were laminated on the porous fuel electrode current collector and the porous air electrode current collector, respectively. In this way, a conventional solid electrolyte fuel cell was produced.

Power generation tests were carried out under the following conditions, by using the solid electrolyte fuel cells 1 to 7 according to the present invention, the comparison solid electrolyte fuel cells 1 to 4, and the conventional solid electrolyte fuel cell, which were obtained in the Example 2 and the conventional example 2.

Temperature: 700° C.,

Fuel gas: hydrogen,

Fuel gas flow rate: 0.34 L/min (=3 cc/nin/cm²),

Oxidizing agent gas: air,

Oxidizing agent gas flow rate: 1.7 L/min (=15 cc/nin/cm²),

Power generation was performed under the above described conditions, to measure the cell voltage, the output power, and the output power density. The results of the measurement are shown in Table 2.

[Table 2]

From a comparison of the solid electrolyte fuel cell 1 to 7 according to the present invention and the conventional solid electrolyte fuel cell, based on the results shown in Table 2, it can be seen that the solid electrolyte fuel cells 1 to 7 according to the present invention exhibit more excellent values in each of the cell voltage, the output power, and the output power density than the conventional solid electrolyte fuel cell. Further, it can also be seen that the comparison solid electrolyte fuel cells 1 to 4 are inferior in at least one of the cell voltage, the output power, the output power density, and the power generation efficiency to the solid electrolyte fuel cells 1 to 7 according to the present invention. From the above comparison and the like, it can be seen that the electrolyte membrane for electrochemical cells excellent in oxide ion permeability according to the present invention is capable of exhibiting an excellent characteristics as an electrolyte membrane of a solid electrolyte fuel cell.

### EXAMPLE 3

A formed body was produced by press forming the samarium strontium cobaltite based cathode raw powder prepared in the Example 1 and having an average grain diameter of 1.1 μm, and was retained at a temperature of 1100° C. for five hours, to thereby produce and prepare an air electrode plate.

The disc-like target made of the lanthane gallate based electrolyte prepared in the Example 1, and the previously prepared air electrode plate were set in the pulsed laser ablation apparatus. The pulsed laser ablation method was carried out under pulsed laser ablation conditions similar to those in the Example 1, while retaining the conditions during the time period shown in Table 1. In this way, electrolyte membranes for electrochemical cells having the thickness shown in Table 1, and a composition expressed by (La_{0.9}Sr_{0.1}) (Ga_{0.8}Mg_{0.2})O₃ were formed on the air electrode plate. The cross section of the electrolyte membranes for electrochemical cells obtained in this way was observed by the scanning electron microscope (SEM), and further, the orientation of perovskite crystal structure of the electrolyte membranes was investigated by X-ray diffraction. As a result, it was found that the same electrolyte membranes for electrochemical cells as those shown in Table 1 were obtained.

The slurry containing the samarium strontium cobaltite based air electrode raw powder was prepared similarly to the Example 1, and applied on the previously formed electrolyte membrane for electrochemical cells at a thickness of 30 μm by the screen printing method, and dried, and thereafter, the air electrode plate was heated and retained in air at 1100° C. for five hours, so that an air electrode membrane was baked on the other face of the electrolyte membrane for electrochemical cells. In this way, an oxygen pump cell was produced.

Porous air electrode current collectors were laminated on the air electrode plate and the air electrode membrane of the oxygen pump cell obtained in this way, respectively, and were attached to a stainless steel container member with an oxygen discharge pipe, so as to be assembled. In this way, oxygen concentrators 1 to 7 according to the present invention and comparison oxygen concentrators 1 to 4, each having a structure shown in FIG. 1, were produced. In FIG. 1, reference numeral 1 denotes an air electrode current collector, 2 denotes an air electrode plate, 3 denotes an electrolyte membrane, 4 denotes an air electrode membrane, 5 denotes an air electrode current collector, and 6 denotes a stainless steel container member with an oxygen discharge pipe.

### CONVENTIONAL EXAMPLE 3

A disc-like lanthanum gallate based solid electrolyte plate having a component composition of (La_{0.9}Sr_{0.1}) (Ga_{0.8}Mg_{0.2})O₃, and having a thickness of 200 μm and a diameter of 50 mm, was produced under the same manufacturing conditions as the conventional example 1. The slurry containing the samarium strontium cobaltite based air electrode raw powder was respectively applied on both faces of the electrolyte plate so as to obtain a diameter of 39.1 mm (≈12 cm²) and a thickness of 30 μm, and dried, and thereafter, the electrolyte plate was heated and retained in air at 1100° C. for five hours, so that the other air electrode membrane was baked. In this way, a conventional oxygen pump cell was produced. A conventional oxygen concentrator having the structure shown in FIG. 1 was produced similarly to the Example 3, by using the conventional oxygen pump cell.

Oxygen concentration tests were carried out under the following conditions by using the oxygen concentrators 1 to 7 according to the present invention, the comparison oxygen concentrators 1 to 4, which were obtained in the Example 3, and the conventional oxygen concentrator obtained in the conventional example 3.

Temperature: 600° C.,

Current density: 1.5 A/cm²

(The oxygen concentration rate is proportional to the current density, and oxygen of about 3 cc/min/cm² is concentrated at the time of 1 A/cm², and hence, oxygen of about 4.5 cc/min/cm² is concentrated under the above described condition of current density: 1.5 A/cm².)

The cell voltage (that is, overvoltage) and the oxygen concentration rate, when the oxygen concentration was carried out under the above described conditions, were measured, and the measurement results are shown in Table 3. Since the comparison was made under the condition of constant current density, the smaller voltage indicates that the smaller amount of electric power is required for concentrating the same amount of oxygen.

[Table 3]

From a comparison of the oxygen concentrators 1 to 7 according to the present invention and the conventional oxygen concentrator, based on the results shown in Table 3, the oxygen concentrators 1 to 7 according to the present invention have smaller voltages than the conventional oxygen concentrator, and hence, are capable of concentrating the same quantity of oxygen with less electric power, that the electrolytes of the comparison oxygen concentrators 1 and 3 are too thin to prevent short circuit between electrodes, making it impossible to measure the voltage, and the comparison oxygen concentrator 2 has a voltage which is lower than that of the conventional oxygen concentrator, but which is higher than the voltages of the oxygen concentrators 1 to 7 according to the present invention, and that the electrolyte of the comparison oxygen concentrator 4 is not fine, thereby causing oxygen to leak and making it impossible to obtain a desired concentration rate. From the above results, or the like, it can be seen that the electrolyte membrane for electrochemical cells according to the present invention has excellent characteristics, when used as an electrolyte membrane of an oxygen pump cell in an oxygen concentrator.

### BRIEF DESCRIPTION OF THE DRAWINGS

FIG. 1 is a cross section for explaining an oxygen concentrator.

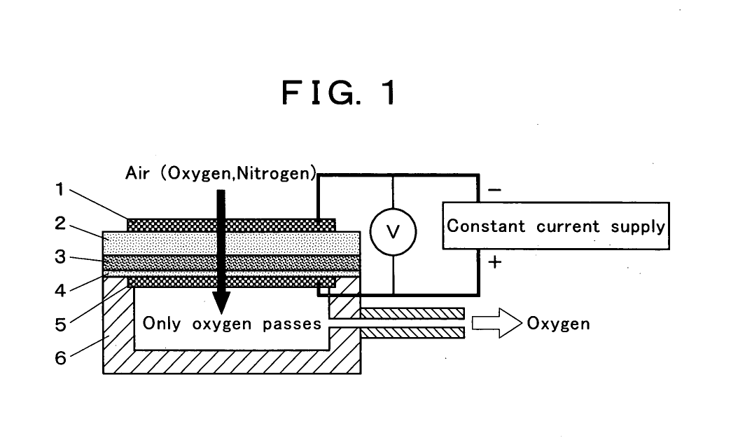

### DESCRIPTION OF SYMBOLS

1: Air electrode current collector
2: Air electrode plate
3: Electrolyte membrane
4: Air electrode membrane
5: Air electrode current collector
6: Stainless steel container member with oxygen discharge pipe

TABLE 1

| | | PULSED LASER | | | | | |
|---|---|---|---|---|---|---|---|
| | | ABLATION | | | | | |
| | | CONDITIONS | | | | | |
| | | OXYGEN | RE- | | | | |
| | | PARTIAL | TAINING | ELECTROLYTE MEMBRANE FOR ELECTROCHEMICAL CELLS | | | MEA- |
| ELECTRO- | | PRES- | TIME | THICK- | | ORIENTATION OF PEROVSKITE | SURED |
| CHEMICAL | | SURE | PERIOD | NESS | SEM | CRYSTAL STRUCTURE OF ELECTROLYTE | CURRENT |
| CELL | | (ATM) | (HOUR) | (μm) | OBSERVATION RESULT | MEMBRANE | VALUE (A) |
| PRESENT | 1 | 0.05 | 0.5 | 1 | COLUMNAR CRYSTAL | [112] DIRECTION OF PEROVSKITE | 600 |
| INVENTION | 2 | 0.05 | 1.5 | 3 | STRUCTURE GROWN TO | CRYSTAL STRUCTURE OF SOLID | 470 |
| | 3 | 0.05 | 2.0 | 4 | MEMBRANE SURFACE | ELECTROLYTE MEMBRANE HAVING | 560 |
| | 4 | 0.05 | 2.5 | 5 | IN THE DIRECTION | COLUMNAR CRYSTAL STRUCTURE | 540 |
| | 5 | 0.05 | 3.0 | 6 | PERPENDICULAR TO | GROWN TO MEMBRANE SURFACE IN THE | 520 |
| | 6 | 0.05 | 4.0 | 8 | MEMBRANE FACE WAS | DIRECTION PERPENDICULAR TO | 505 |
| | 7 | 0.05 | 5.0 | 10 | FORMED | MEMBRANE FACE WAS ORIENTED | 500 |
| COM- | 1 | 0.05 | 0.2 | 0.5* | | PERPENDICULARLY TO MEMBRANE FACE | 470 |
| PARISON | 2 | 0.05 | 5.5 | 11* | POLYCRYSTAL | ISOTROPIC PORTION WAS FORMED | 390 |
| | | | | | WAS FORMED ON | BESIDES PORTION WITH [112] | |
| | | | | | UPPER FACE OF ALL | DIRECTION ORIENTED | |
| | | | | | COLUMNAR CRYSTALS | PERPENDICULARLY TO MEMBRANE FACE | |

| | | | | | |
|---|---|---|---|---|---|
| 3 | 0.0005* | 0.5 | 0.1 | INSUFFICIENT MEMBRANE FORMING RATE | 570 |
| 4 | 0.11* | 0.5 | 1 | INSUFFICIENT DENSENESS | — |

| | | | | | |
|---|---|---|---|---|---|
| CONVENTIONAL | — | 200 | SINTERED STRUCTURE | — | 40 |

*DESIGNATES THAT VALUE IS OUT OF CONDITION OF PRESENT INVENTION

TABLE 2

| | | | | CHARACTERISTIC OF SOLID | | |
|---|---|---|---|---|---|---|
| | | | | ELECTROLYTE FUEL CELL | | |
| | | | | | | OUTPUT |
| SOLID | | USED | | CELL | OUTPUT | POWER |
| ELECTROLYTE | | ELECTROCHEMICAL | | VOLTAGE | POWER | DENSITY |
| FUEL CELL | | CELL IN TABLE 1 | | (V) | (W) | (W/cm²) |
| PRESENT | 1 | PRESENT | 1 | 0.75 | 415 | 3.7 |
| INVENTION | 2 | INVENTION | 2 | 0.70 | 400 | 3.5 |
| | 3 | | 3 | 0.70 | 390 | 3.4 |
| | 4 | | 4 | 0.60 | 362 | 3.2 |
| | 5 | | 5 | 0.59 | 350 | 3.1 |
| | 6 | | 6 | 0.58 | 340 | 3.0 |
| | 7 | | 7 | 0.55 | 310 | 2.7 |
| COMPARISON | 1 | COMPARISON | 1 | 0.50 | 270 | 2.4 |
| | 2 | | 2 | 0.49 | 265 | 2.3 |
| | 3 | | 3 | 0.70 | 400 | 3.5 |
| | 4 | | | — | — | — |

| | | | | |
|---|---|---|---|---|
| CONVENTIONAL | CONVENTIONAL | 0.3 | 200 | 1.8 |

TABLE 3

| | | | | | CHARACTERISTIC OF | | | |
|---|---|---|---|---|---|---|---|---|
| | | | | | OXYGEN CONCENTRATOR | | | |
| | | | | | | | | OXYGEN |
| | | ELECTROLYTE MEMBRANE FOR ELECTROCHEMICAL CELLS | | | LOAD | CELL | RE- | CONCEN- |
| | | THICK- | | ORIENTATION OF PEROVSKITE | CURRENT | VOLT- | QUIRED | TRATION |
| OXYGEN | | NESS | SEM OBSERVATION | CRYSTAL STRUCTURE OF | DENSITY | AGE | POWER | RATE |
| CONCENTRATOR | | (μm) | RESULT | ELECTROLYTE MEMBRANE | (A/cm²) | (V) | (W) | (cc/min) |
| PRESENT | 1 | 1 | COLUMNAR | [112] DIRECTION OF PEROVSKITE | 1.5 | 0.43 | 7.74 | 50 |
| INVENTION | 2 | 3 | CRYSTAL | CRYSTAL STRUCTURE OF SOLID | 1.5 | 0.44 | 7.92 | 52 |
| | 3 | 4 | STRUCTURE GROWN | ELECTROLYTE MEMBRANE HAVING | 1.5 | 0.44 | 7.92 | 53 |
| | 4 | 5 | TO MEMBRANE | COLUMNAR CRYSTAL STRUCTURE | 1.5 | 0.45 | 8.10 | 54 |
| | 5 | 6 | SURFACE IN THE | GROWN TO MEMBRANE SURFACE | 1.5 | 0.45 | 8.10 | 54 |
| | 6 | 8 | DIRECTION | IN THE DIRECTION PERPENDICULAR | 1.5 | 0.46 | 8.28 | 54 |
| | 7 | 10 | PERPENDICULAR | TO MEMBRANE FACE WAS | 1.5 | 0.46 | 8.28 | 54 |
| COM- | 1 | 0.5* | TO MEMBRANE | ORIENTED PERPENDICULARLY TO | IMPOSSIBLE TO MEASURE DUE TO | | | |
| PARISON | | | FACE WAS FORMED | MEMBRANE FACE | SHORT CIRCUIT | | | |
| | 2 | 11* | POLYCRYSTAL WAS | ISOTROPIC PORTION WAS FORMED | 1.5 | 0.56 | 10.08 | 54 |
| | | | FORMED ON UPPER | BESIDES PORTION WITH [112] | | | | |
| | | | FACE OF ALL | DIRECTION ORIENTED | | | | |
| | | | COLUMNAR | PERPENDICULARLY TO | | | | |
| | | | CRYSTALS | MEMBRANE FACE | | | | |

| 3 | 0.1 | INSUFFICIENT MEMBRANE FORMING RATE | IMPOSSIBLE TO MEASURE DUE TO | | | |
|---|---|---|---|---|---|---|
| | | | SHORT CIRCUIT | | | |
| 4 | 1 | INSUFFICIENT DENSENESS | 1.5 | 0.43 | 7.74 | 10 |

| | | | | | | | |
|---|---|---|---|---|---|---|---|
| CONVENTIONAL | 200 | SINTERED | — | 1.5 | 1.08 | 19.44 | 54 |
| | | STRUCTURE | | | | | |

*DESIGNATES THAT VALUE IS OUT OF CONDITION OF PRESENT INVENTION

1. An electrolyte membrane for electrochemical cells that is excellent in oxide ion permeability, and is made of an oxide ion conductor having a component composition expressed by a general formula: La_{1-X}Sr_{X}Ga_{1-Y}Mg_{Y}O₃ (where X=0.05 to 0.3, and Y=0.025 to 0.3), and having a perovskite type crystal structure, wherein the electrolyte membrane has a columnar crystal structure grown to a membrane surface in a direction perpendicular to a membrane face, and the perovskite type crystal structure of the electrolyte membrane having the columnar crystal structure grown to the membrane surface, has a crystal structure with [112] direction oriented perpendicularly to the membrane face.

2. The electrolyte membrane for electrochemical cells excellent in oxide ion permeability, according to claim 1, wherein the electrolyte membrane has a membrane thickness of 1 to 10 μm.

3. An electrochemical cell, wherein a cathode membrane is formed on one of the faces of the electrolyte membrane for electrochemical cells according to one of claim 1 and claim 2, and an anode membrane is formed on the other face.

4. A power generation cell for a solid electrolyte fuel cell, wherein an air electrode membrane is formed on one of the faces of the electrolyte membrane for electrochemical cells excellent in oxide ion permeability, according to one of claim 1 and claim 2, and a fuel electrode membrane is formed on the other face.

5. A solid electrolyte fuel cell incorporating the power generation cell for the solid electrolyte fuel cell according to claim 4.

6. An oxygen pump cell, wherein air electrode membranes are formed on both faces of the electrolyte membrane for electrochemical cells according to one of claim 1 and claim 2.

7. An oxygen concentrator incorporating the oxygen pump cell according to claim 6.

8. A method of producing the electrolyte membrane for electrochemical cells excellent in oxide ion permeability, according to one of claim 1 and claim 2, wherein physical vapor deposition is performed in an oxygen atmosphere by using a target made of a sintered body obtained in a manner that La₂O₃ powder, SrCO₃ powder, Ga₂O₃ powder, and MgO powder are blended and mixed so as to contain 71 to 81% of La, 66 to 106% of Sr, 66 to 77% of Ga, and 250 to 290% of Mg, with respect to a target composition of an electrolyte membrane for electrochemical cells, expressed by a general formula La_{1-X}Sr_{X}Ga_{1-Y}Mg_{Y}O₃ (where X=0.05 to 0.3, Y=0.025 to 0.3), and are then sintered.

9. The method of producing the electrolyte membrane for electrochemical cells excellent in oxide ion permeability, according to claim 8, wherein the physical vapor deposition is performed in an oxygen atmosphere under an oxygen partial pressure of 0.001 to 0.1 atm.

10. The method of producing the electrolyte membrane for electrochemical cells excellent in oxide ion permeability, according to claim 8, wherein the physical vapor deposition is performed by a pulsed laser ablation method.

11. The method of producing the electrolyte membrane for electrochemical cells excellent in oxide ion permeability, according to claim 9, wherein the physical vapor deposition is performed by a pulsed laser ablation method.
